(19) United States
(12) Patent Application Publication
(10) Pub. No.: US 2013/0118556 A1
(43) Pub. Date: May 16, 2013

(54) SOLAR SUNROOF FOR VEHICLE

(71) Applicants: Won Jung KIM, Seoul (KR); Sang Hak KIM, Seoul (KR); Yong Jun JANG, Seongnam (KR); Yong Gu KIM, Hwaseong (KR); Mi Yeon SONG, Seoul (KR); In Woo SONG, Hwaseong (KR); Ji Yong LEE, Hwaseong (KR); Ki Chun LEE, Seoul (KR)

(72) Inventors: Won Jung KIM, Seoul (KR); Sang Hak KIM, Seoul (KR); Yong Jun JANG, Seongnam (KR); Yong Gu KIM, Hwaseong (KR); Mi Yeon SONG, Seoul (KR); In Woo SONG, Hwaseong (KR); Ji Yong LEE, Hwaseong (KR); Ki Chun LEE, Seoul (KR)

(73) Assignee: HYUNDAI MOTOR COMPANY, Seoul (KR)

(21) Appl. No.: 13/489,703

(22) Filed: Jun. 6, 2012

(30) Foreign Application Priority Data
Nov. 15, 2011 (KR) 10-2011-0118605

(51) Int. Cl. H01L 31/042; H01L 31/048

(52) U.S. Cl. 136/249; 136/244; 136/251

(57) ABSTRACT

Disclosed is a solar cell sunroof for a vehicle in which a solar cell using a substrate which can be flexibly bent depending on a curvature of the body of the vehicle is provided. More specifically, the solar sunroof uses a low-priced semi-transparent solar cell. In the solar cell sunroof for a vehicle, a solar cell module is attached to one side of the sunroof. This solar cell module includes a flexible plastic substrate which can be bent along the curved surface of the sunroof, the flexible plastic substrate can be made of polymers including polyethylene, polypropylene, polyester, polyacryl, polyimide, polyamide, and polystyrene, a blend material mixing two or more of the polymers, or a copolymer.

### CROSS-REFERENCE TO RELATED APPLICATION

This application claims under 35 U.S.C. §119(a) the benefit of Korean Patent Application No. 10-2011-0118605 filed on Nov. 15, 2011, the entire contents of which are incorporated herein by reference.

### BACKGROUND

(a) Technical Field

The present invention relates to a solar sunroof for a vehicle. More particularly, it relates to a solar cell sunroof for a vehicle in which a solar cell using a substrate which can be to flexibly bent depending on the curvature of the body of the vehicle, the solar sunroof using a low-priced semi-transparent solar cell.

(b) Background Art

With the growing concerns on eco-friendly energy fields, many studies have recently been focused on photoelectric devices such as solar cells. Among them, next-generation solar cells including dye-sensitized solar cells are considered suitable for Building Integrated Photovoltaics (BIPV) because they can be installed along a smooth curved surface of a building exhibiting beautiful color aesthetics and reflecting visual advantages by which the interior and exterior of the building can be viewed semi-transparently.

Further, silicon solar panels have recently installed on an upper surface of the body of a high-efficiency green vehicle, such as a Hybrid Electric Vehicle (HEV) or an Electric Vehicle (EV), or alternatively a luxury vehicle. The electric power generated by solar cells can be used to operate a fan when an interior temperature of the vehicle increases after being parked in the hot sun for a certain period of time, thereby lowering the interior temperature of the vehicle, making a passenger comfortable, and reducing an in-use time of an air conditioner to improve a fuel efficiency of the vehicle. However, due to the opaqueness, conventional silicon solar cells cannot provide a natural open view through an upper surface, i.e., a sunroof of a vehicle. Furthermore, the conventional sunroofs use high priced silicon solar cells which are not cost effective and increase the vehicle's weight.

Accordingly, there is a need for the development of sunroofs for vehicles using solar cells which allow for transparency and an aerodynamic curvature design, while at the same time provide a cost efficient alternative to the conventional designs.

### SUMMARY OF THE DISCLOSURE

The present invention provides a solar cell sunroof for a vehicle which includes a solar cell module using a plastic substrate which can be flexibly bent depending on a curvature of a body of the vehicle.

The present invention also provides a solar cell sunroof for a vehicle to which a lightweight low-priced solar cell module which can be fixedly attached to a surface of the sunroof is mounted, so that the sunroof becomes lighter, improves manufacturing costs, provides transparency, and maintains an open feeling to the passengers.

In one aspect, the present invention provides a solar cell sunroof for a vehicle, wherein a solar cell module is attached to one side of the sunroof, the solar cell module including a flexible plastic substrate which can be bent along the curved surface of the sunroof, the flexible plastic substrate being made of one selected from polymers consisting of polyethylene, polypropylene, polyester, polyacryl, polyimide, polyamide, and polystyrene, a blend material mixing two or more of the polymers, or a copolymer.

In an exemplary embodiment, the plastic substrates may be manufactured by stacking two or more polymer materials selected from polymers including polyethylene, polypropylene, polyester, polyacryl, polyimide, polyamide, and polystyrene.

In some exemplary embodiment, a visible light transmission of the plastic substrate may be at least 80%, and the plastic substrate may have a thickness of 0.01 to 1 mm.

In some exemplary embodiments, a transparent bonding film having transparent bonding layers on opposite surfaces thereof may be attached between a substrate of the working electrode of the solar cell module and the sunroof. A porous thin electrolyte film may be filled between the working electrode and the counter electrode of the solar cell module.

In some exemplary embodiments, the solar cell module may be attached to one surface of the sunroof by means of a polyvinylbutyrate (PVB) film having a bonding property due to heat and pressure. Furthermore, a cell protecting transparent bonding film having a transparent bonding layer bonded to an outer surface of a substrate for the counter electrode at one surface thereof and a reinforcing coating layer for improving a surface strength on an opposite surface thereof may be attached to one surface of the solar cell module.

Furthermore, the solar cell module may have a cell protecting transparent bonding film having a scattering layer on a surface bonded to an outer surface of a substrate for the counter electrode, and the cell protecting transparent bonding film may have, on an opposite surface thereof, a reinforcing coating layer configured to improve a surface strength.

In a still yet further exemplary embodiment, the working electrode and the counter electrode of the solar cell module may be sealed with a single or dual layer by using one or two or more materials selected from glass frit, a thermosetting polymer, and a UV hardener.

Meanwhile, the solar cell module, which has the above-mentioned construction, may be applicable to others surfaces than sunroofs for vehicles, or it can be constructed as an independent unit.

In another aspect, the present invention provides a solar cell module including a working electrode including a flexible transparent substrate having a semiconductor oxide thick film and a metal grid on a surface coated with a transparent conductive layer; and a counter electrode including a flexible transparent substrate having a catalytic electrode and a metal grid on a surface coated with a transparent conductive layer. The working electrode and the counter electrode may be bonded to each other with an interposed electrolyte.

Each of the transparent substrates may be made of a number of polymers including polyethylene, polypropylene, polyester, polyacryl, polyimide, polyamide, and polystyrene, a blend material mixing two or more of the polymers, and a copolymer. The transparent substrates may be manufactured by stacking two or more polymer materials selected from a group consisting of polyethylene, polypropylene, polyester, polyacryl, polyimide, polyamide, and polystyrene.

The visible light transmission of the transparent substrates may configured to be at least 80%, and the transparent substrates may have a thickness of 0.01 to 1 mm.

The working electrode may have a transparent bonding film attached to an outer surface of its transparent substrate. Alternatively, the working electrode may have a to polyvinylbutyrate (PVB) film, which has a bonding property when applied with heat and pressure, attached to an outer surface of its transparent substrate.

The counter electrode may have a cell protecting transparent bonding film, which has a reinforcing coating layer configured to improve a surface strength, attached to an outer surface of its transparent substrate.

The counter electrode may have a cell protecting transparent bonding film, which has a scattering layer on a surface, attached to an outer surface of its transparent substrate. The cell protecting transparent bonding film may have, on an opposite surface thereof, a reinforcing coating layer configured to improve a surface strength.

As the electrolyte, a porous thin film electrolyte film may be used.

Advantageously, since the solar cell sunroof of the present invention using a plastic substrate with a thin thickness which can be manufactured of a flexible material, be formed to have a thin thickness which can be flexibly bent, and can be flexibly bent by using a flexible material so that it can be curved depending on a curvature of the body of the vehicle, the solar cell module can be flexibly attached to a surface of the sunroof along the curvature of the vehicle.

Since the solar cell sunroof for a vehicle of the present invention uses a flexible and lightweight solar cell module, a design of the vehicle does not need to be changed when a solar cell is attached. Further, an electrolyte can be prevented from being leaked, making it to possible to improve product value and reduce harmful conditions. In addition, short circuits which can be caused when a flexible thin film substrate is used can be improved.

Furthermore, the solar cell sunroof for a vehicle can be improved by preventing an increase in the weight of a thick substrate of the solar cell and thus a decrease of fuel efficiency.

In addition, since the solar cell sunroof for a vehicle of the present invention uses a low-priced lightweight solar cell module with a thin plastic substrate, manufacturing costs can be reduced in comparison with a sunroof which is manufactured using a conventional silicon solar cell. Moreover, the solar cell sunroof can be made lightweight and provide a transparent feeling typically associated with a sunroof by securing at least semi-transparent characteristics

### BRIEF DESCRIPTION OF THE DRAWINGS

The above and other features of the present invention will now be described in detail with reference to certain exemplary embodiments thereof illustrated in the accompanying drawings which are given herein below by way of illustration only, and thus are not limitative of the present invention, and wherein:

FIGS. 1A-B and 2A-B illustrate basic structures of a general dye-sensitized solar cell;

FIGS. 3A-B illustrates sectional views illustrating a solar cell module attached to a sunroof of a vehicle according to an exemplary embodiment of the present invention;

FIGS. 4A to 8 illustrate sunroofs for a vehicle using solar cell modules according to exemplary embodiments of the present invention;

FIG. 9 illustrates a plan view of a solar cell module attached to the sunroof for a vehicle according to the exemplary embodiment of the present invention; and

FIGS. 10A-D illustrate plan views of sunroofs for a vehicle using the solar cell module according to the exemplary embodiment of the present invention.

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, combustion, plug-in hybrid electric vehicles, hydrogen-powered vehicles and other alternative fuel vehicles (e.g. fuels derived from resources other than petroleum).

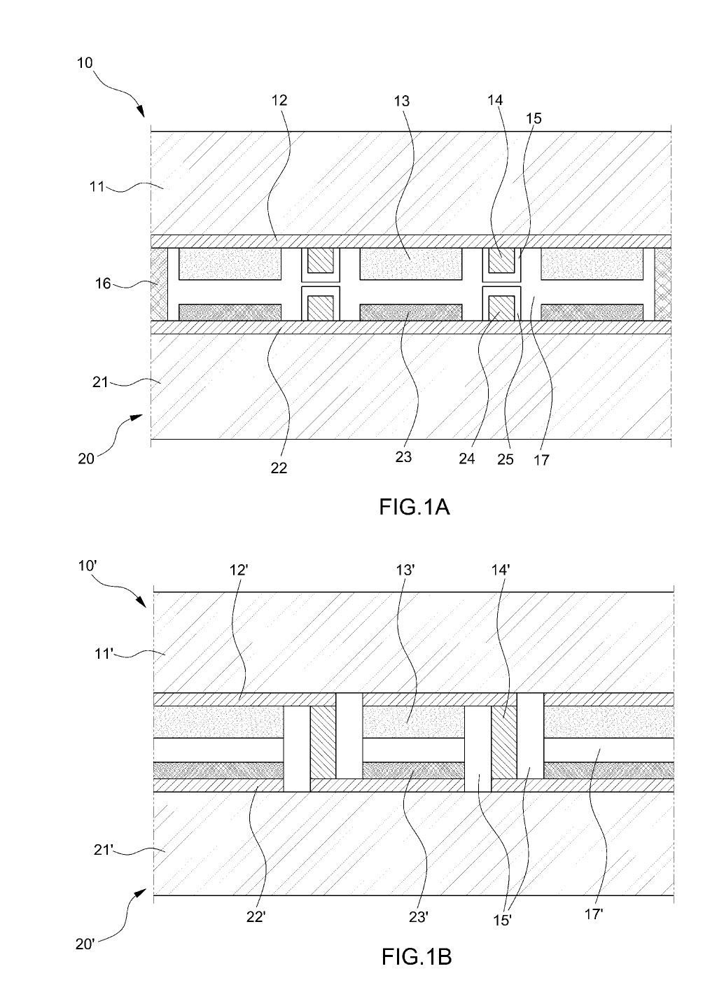

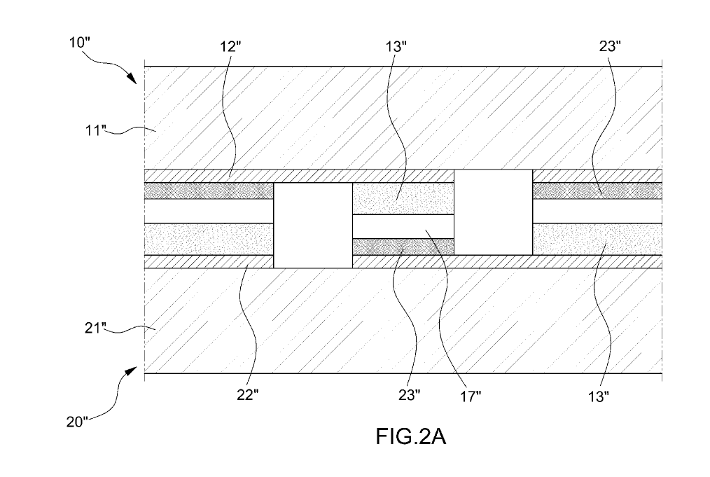

As illustrated in FIG. 1A, a unit dye-sensitized solar cell includes a structure where a working electrode 10 and a counter electrode 20 are bonded to each other with an electrolyte 17 being interposed between them. The solar cell includes a dye (not shown) for absorbing light and emitting electrons, a semiconductor oxide thick film (or electro-optical electrode) 13 coated on an electrode substrate 11 and an electrolyte 17 for filling electrons in the dye from which electrons are emitted. The semiconductor oxide thick film (or electro-optical electrode) 13 consists of porous nanoparticles for moving the emitted electrons to an external electrode The dye is adsorbed on a surface of the electrode substrate 11. The counter electrode 20 includes a catalytic electrode which reduces the oxidized electrolyte.

The catalytic electrode 23 is an electrode made of platinum acting as a catalyst, and is located between metal electrode protecting layers 25. The working electrode 10 and the counter electrode 20 includes transparent substrates 11 and 21 coated with transparent conductive layers (TCOs) 12 and 22 such as Fluorine Doped Tin Oxides (FTOs) respectively so that photoelectrons can move therebetween. Preferably, the transparent substrates 11 and 21 are made of a glass material.

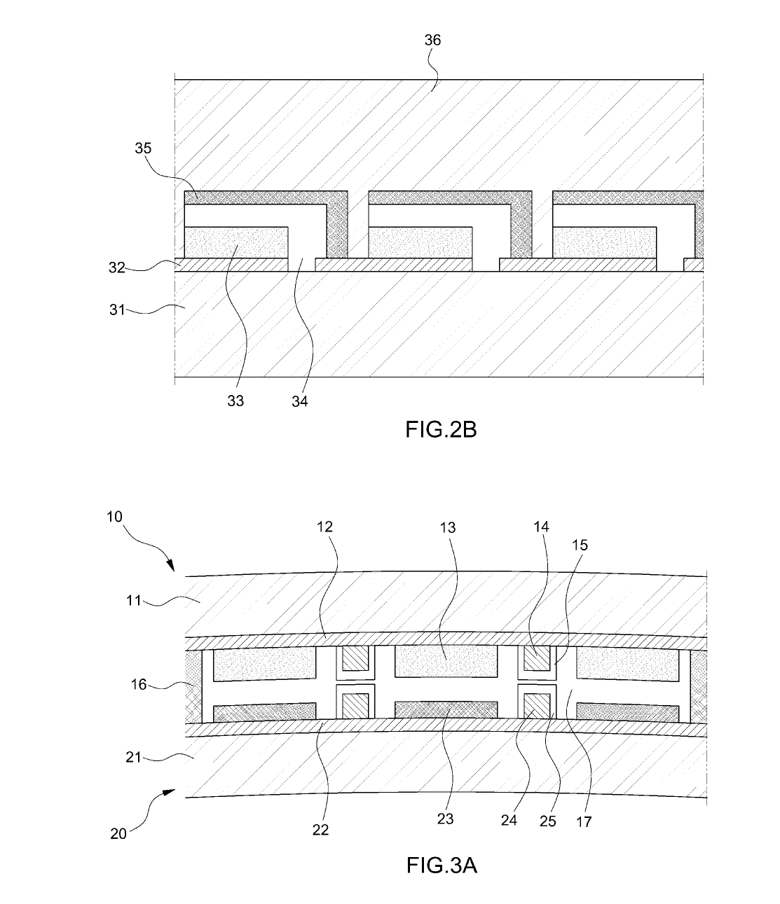

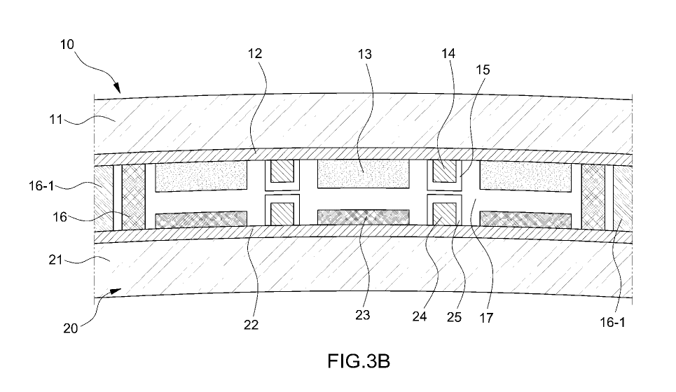

Although the embodiment of the present invention will be described with reference to a parallel structure of FIG. 3 having the same structure as that of FIG. 1A which is a basic structure of a dye-sensitized solar cell module, the present invention is not limited thereto but may be additionally applied to a Z-type structure of FIG. 1B where cells are connected to each other in series, a W-type structure of FIG. 2C where optical electrodes 13″ and catalytic electrodes 23″ are alternately formed on transparent substrates 11″ and 21″, and a monolithic structure of FIG. 2D where optical electrodes 33 and catalytic electrodes 35 of cells are formed on one substrate 31.

Referring to FIG. 1A, in addition to the above-described structure, the dye-sensitized solar cell includes metal electrodes (or metal grids) 14 and 24 acting as current collectors and metal electrode protection layers 15 and 25 for protecting metal electrodes 14 and 24 to prevent corrosion of the metal electrodes 14 and 24 in the working electrode 10 and the counter electrode 20 respectively. Here, in general, the metal electrodes 14 and 24 are inserted in the form of grids to minimize a decrease in efficiency due to a large area of a sub-module when the sub-module is manufactured to have a size larger than that of a unit cell.

Currently, the transparent substrates are generally made of soda-lime glass, or alternatively of a special glass such as low-iron glass to increase optical transmittance. The transparent substrates generally have a thickness of about 2 mm or more to endure an external impact, and accordingly the solar cell has a thickness of about 4 mm or more when it is manufactured.

Additionally, reinforced glass may be used as the glass material for a sunroof of a vehicle to secure the safety of a passenger, and the general thickness of the sunroof is known to be approximately 4 mm. Thus, when a solar cell manufactured in a general method is mounted to a sunroof, the thickness of the sunroof becomes at least about 8 mm, thereby increasing the weight of the vehicle and increasing the required amount of fuel. Further, since the increased thickness increases the interference with the operation of the sunroof due to the solar cell, a conventional design of the vehicle must be changed, causing an increase in costs. Accordingly, it is advantageous that a solar cell of a sunroof of a vehicle is relatively thin and lightweight.

Another item to be considered when a dye-sensitized solar cell is applied to a vehicle is an electrolyte. A liquid electrolyte having a viscosity similar to that of water is mainly used as an electrolyte for a dye-sensitized solar cell. When the dye-sensitized solar cell using a liquid electrolyte is mounted to a vehicle, the electrolyte may be leaked due to an accident and its product value may be decreased. Further, secondary damage may be caused to a passenger due to its harmful characteristics, making it difficult to use the electrolyte.

In recent years, although studies on viscous gel type electrolytes, and even solid electrolytes have been actively made to improve the leakage problem of liquid electrolytes, their performances are generally not as good as a liquid electrolyte. In addition, although a gel type electrolyte has a viscosity higher than that of a liquid electrolyte, it can still be leaked due to an accident. Alternatively, a solid electrolyte has a very low performance, so it cannot be applied to a vehicle.

Accordingly, the present invention provides a solar cell module and a low-priced and lightweight sunroof including the same, which are made suitable for a sunroof of a vehicle by decreasing the thickness of the transparent substrates and preventing the leakage problem typically associated with electrolytes.

Hereinafter, an exemplary embodiment of the present invention will be described in detail with reference to the accompanying drawings.

The solar cell module for a sunroof according to the present invention uses flexible transparent substrates which can be bent depending on a surface structure of the sunroof. Accordingly, the transparent substrates may be made of a flexible material, a thin material which can be flexibly bent, or a thin substrate which can be flexibly bent using a flexible material.

In more detail, flexible plastic substrates 11 and 21 are employed as the transparent substrates instead of glass substrates, and the solar cell module using the plastic substrates 11 and 12 are mounted to the sunroof of the present invention. Preferably, a visible light transmission of the plastic substrates 11 and 21 is at least 80% in order to maintain an efficiency of the solar cell module. Transparent substrates made of either polymers including polyethylene, polypropylene, polyester, polyacryl, polyimide, polyamide, and polystyrene, a blend material mixing two or more of the polymers, or a copolymer may be used as the plastic substrates 11 and 21. Alternatively, two or more polymer materials selected from polymers including polyethylene, polypropylene, polyester, polyacryl, polyimide, polyamide, and polystyrene may be stacked to be used as the plastic substrates 11 and 21.

In more detail, for example, the plastic substrates 11 and 21 may be transparent substrates formed of polycarbonate (PC), polyethersulfone (PES), cyclic olefin copolymer (COC), polyethylene (PE), polyethyleneterephthalate (PET), polyethylenenaphthalate (PEN), triacetylcellulose (TAC), polymethylmethacrylate (PMMA), polyetheretherketone (PEEK), polyamide (PA), polyimide (PI), polyetherimide (PEI), polypropylene (PP), or polypropylene (OPP, oriented).

In applying the plastic substrates 11 and 21 formed of the above-listed materials to a solar cell module for a vehicle, it is advantageous to apply a flexible film form which can be attached to a surface of the sunroof having a predetermined curvature to the plastic substrates to 11 and 21 in order to provide a consistent smooth surface and appearance, and it is also preferable that the plastic substrates 11 and 21 are manufactured of PC, PES, PEI, PEEK, PI, etc., taking into consideration a thermal resistance. Thus, the plastic substrates 11 and 21 are manufactured to have a thin thickness such as a film, and may be flexible thin film substrates having a thickness of about 0.01 to 1 mm.

In the exemplary embodiment of FIG. 3, transparent PI films having a thickness of about 25 μm are used for the plastic substrates 11 and 21 of the working electrode 10 and the counter electrode 20. In this way, as the plastic substrates with a thickness of about 25 μm are used for the substrates 11 and 21 of the working electrode 10 and the working electrode 20, a thickness of a conventional solar cell module which is typically more than 4 mm can be reduced to a thickness of 50 μm, thus reducing the weight of a solar cell module, and making the solar cell module lightweight.

Since an interval (distance) between a working electrode and a counter electrode of a solar cell module is generally around about 50 μm, a thickness of a solar cell module may be reduced to about 100 μm by using a plastic substrate with a relatively thin thickness, advantageously making it possible to construct a solar cell sunroof of the present invention by applying the solar cell module to the sunroof without having to change a design of the vehicle.

A gap between the working electrode 10 and the counter electrode 20 may be generally adjusted by using a sealing agent. When thin and light plastic substrates 11 and 21 are used, the working electrode 10 and the counter electrode 20 may be sealed with a single or dual layer by using one, or two or more materials selected from glass frit, a thermosetting polymer, and a UV hardener.

An example of sealing the working electrode 10 and the counter electrode 20 with a dual layer by using a thermosetting polymeric material and a UV hardener is illustrated in FIG. 3B. The reference numerals 16 and 16-1 denote sealing parts 16 and 16-1 sealing the working electrode 10 and the counter electrode 20 with a dual layer.

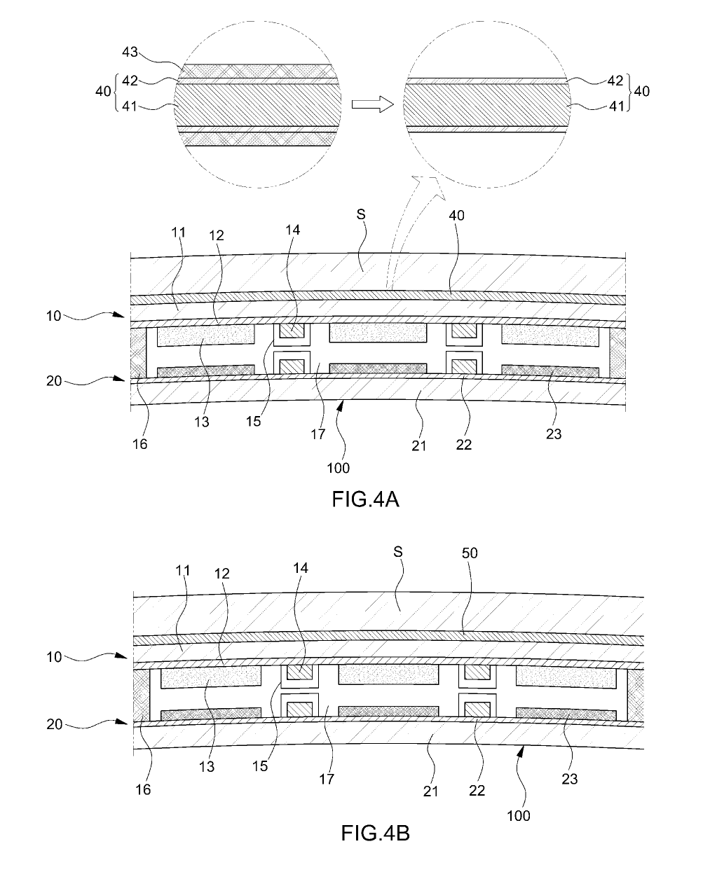

As mentioned above, while there may be various methods of mounting a manufactured solar cell module to a top surface or a sunroof of a vehicle, a simple structure reduces manufacturing costs, examples of which are illustrated in FIGS. 4 to 8.

Since the solar cell module suggested by the present invention uses flexible plastic substrates 11 and 21 with a relatively thin thickness, it may be fixedly attached to an inner surface of a sunroof S by using a transparent bonding film 40. FIG. 4A is a view illustrating a structure where an outer surface of the working electrode 10 of the solar cell module is attached to an inner surface of the sunroof S of the vehicle by using the transparent bonding film 40.

In more detail, the transparent bonding film 40 for attaching the solar cell module to the sunroof S includes a base 41, transparent bonding layers 42 applied to opposite sides of the base 41, and release films 43 attached to the transparent bonding layers 42 on the opposite sides of the base 41 for easy treatment of the transparent bonding film 40. The base 41 may be a film made of any polymeric material such as polyethylene, polypropylene, polyester, polyacryl, polyamide, or polystyrene, or be a film made of a blend obtained by mixing them or a copolymer or a film made by stacking the polymeric materials with at least two layers. The base 41 of the transparent bonding film 40 preferably has a visible light transmission of at least 80%.

The enlarged view of FIG. 4A is a sectional view illustrating the transparent bonding film 40 employed between the working electrode 10 and the sunroof S, and illustrates the structure of the transparent bonding film 40 at an initial stage before it is attached between the solar cell module 100 and the vehicle sunroof S. The transparent bonding film 40 attached to a surface of the electrode substrate (i.e., plastic substrate) 11 according to the present invention is manufactured in the form of FIG. 4A, and is attached to an outer surface of the working electrode 10 in a process of manufacturing the solar cell module.

Accordingly, as partially mentioned above, the transparent bonding film 40 is formed by stacking transparent bonding layers so as to be bonded to the plastic substrates 11 on opposite sides of the base 41, and the release films attached to the transparent bonding layers 42 on the opposite surfaces of the base 41 for easy treatment of the transparent bonding film 40.

A film made of any polymeric material used for a transparent film material may be used for the release films 43, and a surface of each of the release film may be coated with an excellent releasable material such as a silicon or fluorocarbon resin so that it can be easily separated after being attached to the transparent bonding layer 42.

An adhesive used to form the transparent bonding layers 42 may be preferably an optical transparent bonding material used for a display such as a touch screen or lamination of an optical film, which does not degrade transparency of the transparent bonding film 40 optically. In more detail, the adhesive may be a material such as epoxy, acryl, urethane, modified acryl, modified urethane, or modified elastomer.

Since the release film 43 is a disposable film simply used to protect a surface of the transparent bonding film 40, it reduces manufacturing costs by using a low-priced material such as polyester if possible. Furthermore, since the solar cell module 100 of the exemplary embodiment of the present invention is relatively thin and light in comparison to the conventional design, it may be attached to one surface of the sunroof S using the transparent bonding film 40.

Another means for attaching the solar cell module 100 to the vehicle sunroof S may be a PVB (polyvinylbutyrate) film 50 for bonding dual glasses used when a front glass of a vehicle is manufactured. This allows the solar cell module 100 to be attached to the sunroof S while at the same time preventing degradation in transparency of the solar cell module 100 by applying heat at around 200 degrees Celsius and at a predetermined pressure. In this embodiment, the PVB film 50 becomes adhesive due to heat and pressure, so that the solar cell module 100 can be attached to an inner surface of the sunroof S. A structure where the solar cell module 100 is bonded to the vehicle sunroof S using a PVB film 50 is illustrated in FIG. 4B.

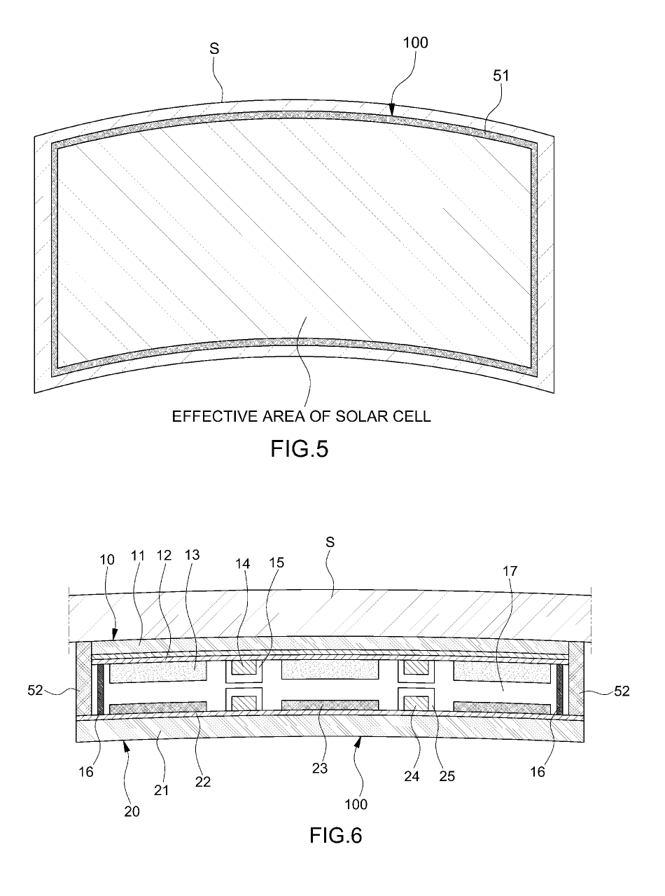

FIG. 5 is a plan view illustrating another structure for attaching the solar cell module to the vehicle sunroof S, and illustrates a shape of the sunroof viewed from the outside of the vehicle. In the embodiment of FIG. 5, only an outskirt portion (a portion of the substrate where an optical electrode is not stacked) of the optical electrode 13 (an effective area) which does not generate a substantial amount of electric power on a surface of the working electrode 10 of the solar cell module 100 is attached to the sunroof S. In particular, a bonding layer 51 may be formed between the working electrode 10 and the sunroof S using the above-mentioned transparent bonding film or PVB film or using an UV hardener or a general adhesive.

FIG. 6 is a view illustrating another structure for attaching the solar cell module to the vehicle sunroof, wherein a size of the substrate 21 of the counter electrode is made larger than that of the substrate 11 of the working electrode 10, and only a peripheral portion of the substrate 21 for the counter electrode exceeding an outer portion of the substrate 11 for the working electrode is applied with a UV hardener or a general adhesive so that the solar cell module 100 can be attached to an inner surface of the sunroof S.

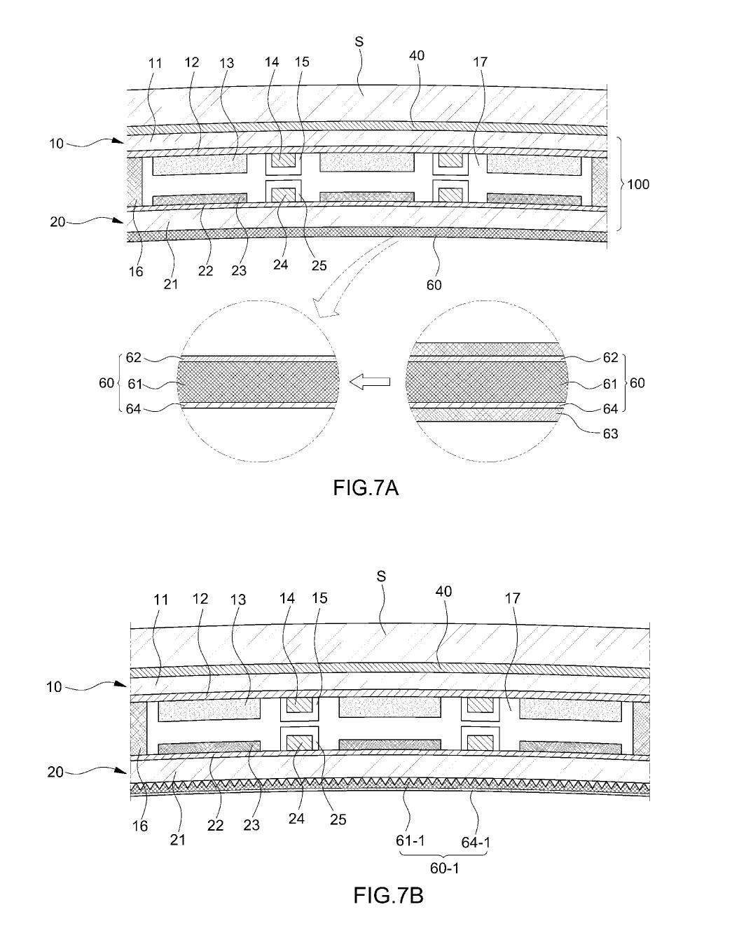

FIG. 7A is a view illustrating a structure for protecting the solar cell module 100 attached to the sunroof of a vehicle from an interior of the vehicle. More specifically, a cell protecting transparent bonding film 60 is attached to an outer surface (a surface of an interior of the vehicle) of the substrate 21 of the counter electrode of the solar cell module 100 attached to the sunroof S.

Since the solar cell is directly exposed to a passenger in an interior of the vehicle, the solar cell may be protected by using the cell protecting transparent bonding film 60. The cell protecting transparent bonding film 60 has a structure similar to that of the above-described transparent bonding film 40, but is formed with a reinforcing coating layer to 64 on one surface of the base 61 instead of the transparent bonding layer 42 to improve a surface strength.

In more detail, the cell protecting transparent bonding film 60 includes a base 61, a transparent bonding layer 62 and a reinforcing coating layer 64 stacked and formed on opposite surfaces of the base 61, release films 63 detachably attached to an outer surface of the transparent bonding layer 62, and a protective film 63-1 detachably attached to an outer surface of the reinforcing coating layer 64. The reinforcing coating layer 64 is formed to reinforce a surface strength by coating a thermosetting material or a UV hardening material on one surface of the base 61. The reinforcing coating layer 64 is formed by coating the transparent bonding layer 62 on one surface of the base 61 bonded to the substrate 21 for the counter electrode and coating a reinforcing material (a thermosetting or UV hardening material) on an opposite surface of the base 61 facing an interior of the vehicle.

The release film 63 protects the transparent bonding layer 62 on one surface of the base 61, and the protective film 63-1 protects the reinforcing coating layer 64 on an opposite surface of the base 61. The protective film 63-1 is configured to be easily separated from the transparent bonding film 60 by coating a material with a weak bonding force at a portion contacting the reinforcing coating layer 64, and the release film 63 and the protective film 63-1 are separated when the cell protecting transparent bonding film 60 is attached to the solar cell module 100.

Moreover, as in FIG. 7B, a scattering layer illustratively formed on one surface of the base 61-1 of the cell protecting transparent bonding film 60-1 so that light entering the solar cell module 100 can be scattered within the solar cell module 100, making it possible to reduce loss of light immediately exiting to the outside and improving the efficiency of the solar cell. That is, the cell protecting transparent bonding film 60-1 has a scattering layer configured to scatter light entering the solar cell module 100, reduce loss of light, and improve an efficiency of the solar cell on one surface of the base 61-1 bonded to the substrate 21 of the counter electrode 20.

The scattering layer may have an uneven structure having a pyramidal shape such as a saw-tooth shape on one surface of the base 61-1 or may have an uneven structure, one surface of which has an uneven height due to attaching various beads with different sizes on the transparent bonding layer.

Although not illustrated in the drawings, a light reflecting layer may be formed on one surface (e.g., attached to an outer surface of the substrate for the counter electrode) of the cell protecting transparent bonding film by using a member, such as aluminum foil or a mirror, which can reflect light, and can have the same effect as the scattering layer on one surface of the cell protecting transparent bonding film 60-1.

Furthermore, since when the cell protecting transparent bonding film having the light reflecting layer is applied to the sunroof of the vehicle, it degrades brightness, it is preferable to avoid using within portions of the vehicle that require a certain degree of brightness.

Further, although not illustrated in the drawings, a solar cell exposed to an interior of a vehicle may be protected by directly coating a thermosetting material or a UV hardening material on an outer surface of the substrate 21 of the counter electrode 20.

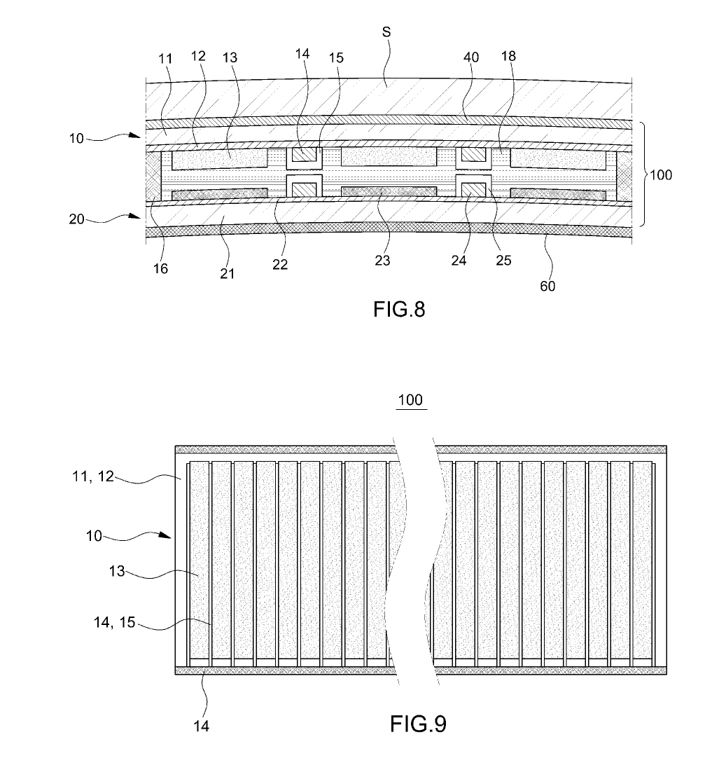

As illustrated in FIG. 8, in a sunroof for a vehicle according to another embodiment of the present invention, a porous thin film electrolyte film 18 having a water proofing function and a short-circuit prevention function may be disposed within the solar cell module 100, i.e., between the working electrode 10 and the counter electrode 20, instead of the liquid electrolyte, and other structures may be configured as in the above-mentioned embodiments. The porous thin film electrolyte film 18 is manufactured by impregnating a porous thin film in an electrolyte, and may be manufactured through a manufacturing method of Korean Patent Application No. 2011-68133, which is hereby incorporated by reference in its entirety.

As illustrated in FIG. 8, since the porous thin film electrolyte film 18 is formed between the working electrode 10 and the counter electrode 20 instead of the conventional liquid electrolyte, the electrolyte cannot be leaked. Further, since an electrolyte inlet port is not required when the solar cell module is manufactured, a product value improves. In addition, since the flexible plastic substrates 11 and 21 which have been described in the above-mentioned embodiments are applied, the porous thin film electrolyte film 18 can act as a spacer for preventing a short circuit which can be generated while the working electrode 10 and the counter electrode 20 come in contact each other due to vibrations and impacts.

Although an example of a sunroof structure having a solar cell module 100 illustrated in the above-mentioned embodiments is illustrated in the embodiment of FIG. 8, the present invention is not limited thereto and another embodiment of the present invention may be realized by applying the porous thin film electrolyte film 18 to various types of solar cell modules.

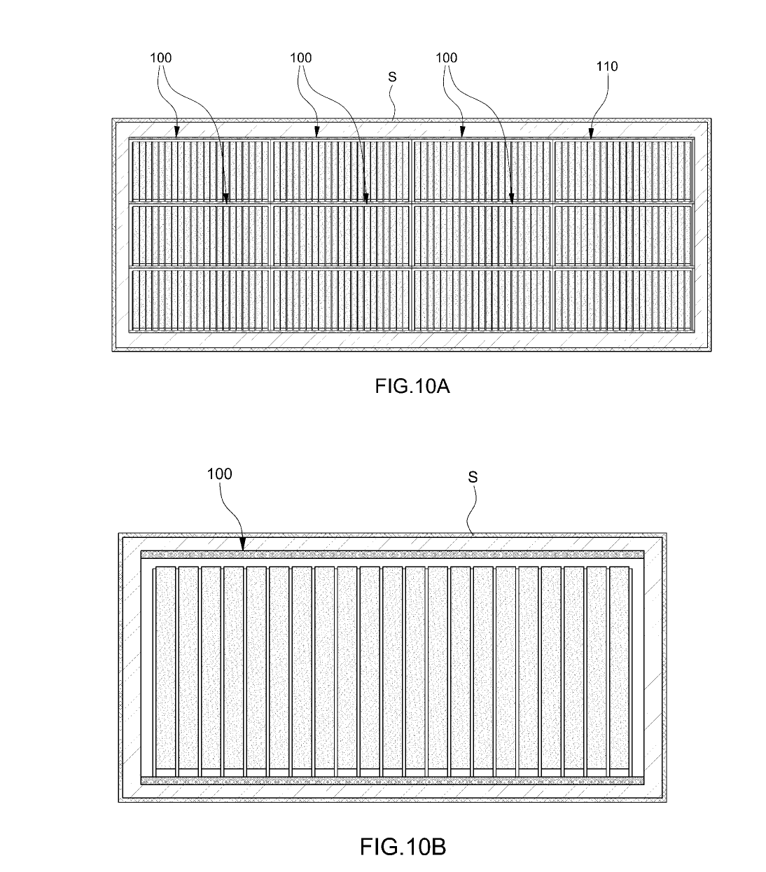

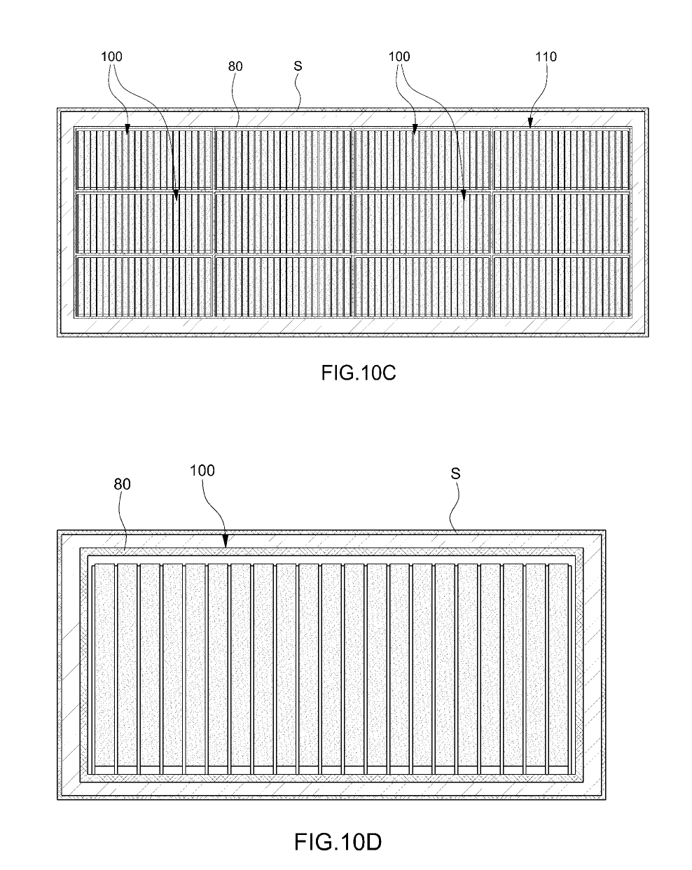

FIG. 9 is a view illustrating an example of a solar cell module which has been described in the above embodiments and illustrates a parallel solar cell module. More specifically, FIG. 9 is a view illustrating the solar cell module 100 viewed from the top of the working electrode 10, wherein the counter electrode 20 is located below the working electrode 10. When the sunroof for a vehicle according to the exemplary embodiment of the present invention is configured by using the solar cell module 100, it is viewed in the form of FIG. 10B from the outside of the vehicle.

The number of solar cell modules 100 attached to the sunroof S may be variously changed depending on a size of the sunroof S and a size of the solar cell module 100 attached to the sunroof S. That is, one solar cell module 100 may occupy an entire area of the sunroof S as in FIG. 10B, or a solar cell array 110 where a plurality of solar cell modules 100 are connected to each other may occupy an entire area of the sunroof S as in FIG. 10A.

Although when a plurality of solar cell modules 100 are connected to each other as in FIG. 10A, the solar cell modules 100 arranged longitudinally are connected in series and the solar cell modules 100 arranged transversely are connected in parallel. These connections may be changed if necessary, considering the specifications of the solar cell module such as an output, a voltage, and a current.

As illustrated in FIGS. 10C and 10D, a solar cell module 100 manufactured by masking a portion of the solar cell module 100 except for an actually effective area (area of an optical electrode) may be attached to the sunroof S of the vehicle. The portion of the solar cell module 100 except for the actually effective area may be masked by directly being coated on the sunroof S or being coated on a periphery of the solar cell module 100.

The invention has been described in detail with reference to exemplary embodiments thereof. However, it will be appreciated by those skilled in the art that changes may be made in these embodiments without departing from the principles and spirit of the invention, the scope of which is defined in the appended claims and their equivalents.

What is claimed is:

1. A solar cell sunroof for a vehicle, comprising a solar cell module attached to one side of the sunroof, the solar cell module including a flexible plastic substrate configured to be bent along the curved surface of the sunroof, the flexible plastic substrate made of one selected from a group consisting of polymers including polyethylene, polypropylene, polyester, polyacryl, polyimide, polyamide, and polystyrene, a blend material mixing two or more of the polymers, and a copolymer.

2. The solar cell sunroof of claim 1, wherein the plastic substrates is manufactured by stacking two or more polymer materials selected from a group consisting of polyethylene, polypropylene, polyester, polyacryl, polyimide, polyamide, and polystyrene.

3. The solar cell sunroof of claim 1, wherein a visible light transmission of the plastic substrate is at least 80%.

4. The solar cell sunroof of claim 1, wherein the plastic substrate has a thickness of 0.01 to 1 mm.

5. The solar cell sunroof of claim 1, wherein a transparent bonding film having transparent bonding layers on opposite surfaces thereof is attached between a substrate of the working electrode of the solar cell module and the sunroof.

6. The solar cell sunroof of claim 1, wherein a porous thin electrolyte film is filled between the working electrode and the counter electrode of the solar cell module.

7. The solar cell sunroof of claim 1, wherein the solar cell module is attached to one surface of the sunroof by a polyvinylbutyrate (PVB) film having a bonding property when applied with heat and pressure.

8. The solar cell sunroof of claim 1, wherein a cell protecting transparent bonding film having a transparent bonding layer is bonded to an outer surface of a substrate for the counter electrode on one surface thereof and a reinforcing coating layer configured to improve a surface strength on an opposite surface thereof is attached to one surface of the solar cell module.

9. The solar cell sunroof of claim 1, wherein the solar cell module has a cell protecting transparent bonding film having a scattering layer on a surface bonded to an outer surface of a substrate for the counter electrode.

10. The solar cell sunroof of claim 9, wherein the cell protecting transparent bonding film has, on an opposite surface thereof, a reinforcing coating layer configured to improve a surface strength.

11. The solar cell sunroof of claim 1, wherein the working electrode and the counter electrode of the solar cell module are sealed with at least one layer by using one or more materials selected from a group consisting of glass frit, a thermosetting polymer, and a UV hardener.

12. A solar cell module comprising:
a working electrode including a flexible transparent substrate having a semiconductor oxide thick film and a metal grid on a surface coated with a transparent conductive layer; and
a counter electrode including a flexible transparent substrate having a catalytic electrode and a metal grid on a surface coated with a transparent conductive layer, wherein
the working electrode and the counter electrode are bonded to each other with an interposed electrolyte.

13. The solar cell module of claim 12, wherein each of the transparent substrates is made of one selected from a group consisting of polymers including polyethylene, polypropylene, polyester, polyacryl, polyimide, polyamide, and polystyrene, a blend material mixing two or more of the polymers, and a copolymer.

14. The solar cell module of claim 12, wherein two or more polymer materials selected from a group consisting of polyethylene, polypropylene, polyester, polyacryl, polyimide, polyamide, and polystyrene, are stacked together to form the transparent substrate.

15. The solar cell module of claim 12, wherein a visible light transmission of the transparent substrates is at least 80%.

16. The solar cell module of claim 12, wherein the transparent substrates have a thickness of 0.01 to 1 mm.

17. The solar cell module of claim 12, wherein the working electrode has a transparent bonding film attached to an outer surface of its transparent substrate.

18. The solar cell module of claim 12, wherein the electrolyte comprises porous thin film electrolyte film.

19. The solar cell module of claim 12, wherein the working electrode has a polyvinylbutyrate (PVB) film, which has a bonding property when applied with heat and pressure, attached to an outer surface of the transparent substrate.

20. The solar cell module of claim 12, wherein the counter electrode has a cell protecting transparent bonding film, which has a reinforcing coating layer configured to improve a surface strength, attached to an outer surface of its transparent substrate.

21. The solar cell module of claim 12, wherein the counter electrode has a cell protecting transparent bonding film, which has a scattering layer on a surface, attached to an outer surface of its transparent substrate.

22. The solar cell module of claim 21, wherein the cell protecting transparent bonding film has, on an opposite surface thereof, a reinforcing coating layer configured to improve a surface strength.
